(19) United States
(12) Patent Application Publication
(10) Pub. No.: US 2009/0065836 A1
(43) Pub. Date: Mar. 12, 2009

(54) SEMICONDUCTOR DEVICE HAVING MIM CAPACITOR AND METHOD OF MANUFACTURING THE SAME

(75) Inventor: Min Seok KIM, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/185,625

(22) Filed: Aug. 4, 2008

(30) Foreign Application Priority Data
Sep. 6, 2007 (KR) 10-2007-0090205

(51) Int. Cl. H01L 29/94; H01L 21/20

(52) U.S. Cl. 257/296; 438/393; 257/E29.345; 257/E21.09

(57) ABSTRACT

A semiconductor device having an MIM capacitor and a method of manufacturing the same. In one example embodiment, a semiconductor device having an MIM capacitor includes a lower electrode including a pair of metal patterns spaced apart from each other, a dielectric formed so as to cover the surfaces of the spaced-apart metal patterns of the lower electrode, a metal plug formed on the dielectric, and an upper electrode made of a metal and formed on the metal plug.

### CROSS-REFERENCE TO A RELATED APPLICATION

This application claims the benefit of Korean Patent Application No. 10-2007-0090205, filed on Sep. 6, 2007 which is hereby incorporated by reference as if fully set forth herein.

### BACKGROUND

1. Field of the Invention

Embodiments of the present invention relate to a semiconductor device having a Metal Insulator Metal (MIM) capacitor and, more particularly, to a semiconductor device having an MIM capacitor which can improve capacitance while decreasing the capacitor area, and a method of manufacturing the same.

2. Description of the Related Art

Use of and interest in merged memory and logic semiconductor devices is increasing. A merged memory and logic device is a structure where a memory, such as a DRAM, and a logic, such as a logic circuit, are implemented in a single chip. Implementation of a memory and a logic in a single chip in a merged memory and logic semiconductor device is advantageous over conventional chips as high-speed and low-power driving is possible without any particular change in design.

In merged memory and logic semiconductor devices, a capacitor formed in a logic region is generally formed in a Metal Insulator Metal (MIM) structure, rather than in a Polysilicon Insulator Polysilicon (PIP) structure. Among passive devices that are used in an RF band, a capacitor requires a high Quality (Q) factor value so that it can be used in an analog circuit of an RF band. To realize a high Q factor, it is necessary to employ a metal with little depletion and low resistance.

With reference now to FIG. 1, a prior art semiconductor device having an MIM capacitor, and a method of manufacturing the same, will be briefly described. As disclosed in FIG. 1, an MIM capacitor 110 includes a lower electrode 112 made of a metal, a dielectric 114 stacked on the lower electrode 112 so as to expose both peripheries of the lower electrode 112, and an upper electrode 116 made of a metal. A first plug 126 is in contact with both the exposed peripheral portions of the lower electrode 112 and a first metal line 132 is formed on the first plug 126. In addition, at least one second plug 128 is in contact with the upper electrode 116, and a second metal line 134 is formed on the second plug 128.

Manufacturing the semiconductor device having the MIM capacitor 110 of FIG. 1 involves several steps. First, a via pattern 104 is formed in the first interlayer insulating film 102. The via pattern 104 is formed so as to contact a predeposition layer (not shown) that includes a transistor. Next, a first metal film, a dielectric film, and a second metal film are sequentially formed on the first interlayer insulating film 102. Then, the second metal film and the dielectric film are etched to form an upper electrode 116 and a dielectric 114. The first metal film is also etched to form the lower electrode 112, thereby forming an MIM capacitor 110 having a planarization structure. At the time of the formation of the lower electrode 112, a circuit line 108 contacting the via pattern 104 is formed. The dielectric 114 and the upper electrode 116 are formed so as to expose each of the peripheral portions of the lower electrode 112.

With continued reference to FIG. 1, a second interlayer insulating film 120 is formed on the first interlayer insulating film 102 and the MIM capacitor 110. Then, the surface of the second interlayer insulating film 120 is planarized by a Chemical Mechanical Polishing (CMP) process. Next, the second interlayer insulating film 120 is etched to form first via holes V1 and second via holes V2 for exposing both peripheral portions of the lower electrode 112 and at least one portion of the upper electrode 116, respectively.

Next, a barrier film 122 is deposited on the surfaces of the first via holes V1 and second via holes V2 and on the second interlayer insulating film 120. Then, a tungsten film 124 is deposited on the barrier film 122 so as to fill the first via holes V1 and second via holes V2. Then, CMP is performed on the tungsten film 124 and the barrier film 122 so as to expose the second interlayer insulating film 120, thus forming first plugs 126 and second plugs 128 contacting the lower electrode 112 and the upper electrode 116, respectively, within the first via holes V1 and second via holes V2. Thereafter, a third metal film is deposited on the second interlayer insulating film 120. Then, the third metal film is etched, to thus form first metal lines 132 contacting the first plugs 126 and second metal lines 134 contacting the second plugs 128.

However, the prior art semiconductor device having an MIM capacitor of FIG. 1 suffers from a problem in that a desired level of capacitance cannot be achieved due to a decrease in capacitor area resulting from high integration. It is necessary for a merged memory and logic semiconductor device to have a high capacitance per unit area in order to obtain a high Q value and a low voltage rate. To increase capacitance, the enlargement of the electrode area is required. Hence, the prior art MIM capacitor structure leads to an increase in chip size which hinders high integration.

### SUMMARY OF EXAMPLE EMBODIMENTS

In general, example embodiments of the invention relate to a semiconductor device having a Metal Insulator Metal (MIM) capacitor, which can achieve a desired capacitance despite a decreased capacitor area, and a method of manufacturing the same.

In one example embodiment, a semiconductor device having an MIM capacitor includes a lower electrode including a pair of metal patterns spaced apart from each other, a dielectric formed so as to cover the surfaces of the spaced-apart metal patterns of the lower electrode, a metal plug formed on the dielectric, and an upper electrode made of a metal and formed on the metal plug.

In another example embodiment, a semiconductor device having an MIM capacitor includes a metal line, a first interlayer insulating film formed so as to cover the metal line, a pair of first via patterns spaced apart from each other in the first interlayer insulating film so as to be in contact with the metal line, and a lower electrode including a pair of metal patterns formed on the first interlayer insulating film. The pair of metal patterns of the lower electrode are spaced apart from each other and formed so as to be in contact with the first via patterns, respectively. The semiconductor device having an MIM capacitor further includes a second interlayer insulating film formed on the first interlayer insulating film. The second interlayer insulating film has a hole for exposing the lower electrode and the first interlayer insulating film adjacent thereto. The semiconductor device having an MIM capacitor further includes a dielectric formed on the surface of the hole, a metal plug formed on the dielectric so as to fill the hole, and an upper electrode made of a metal formed on the second interlayer insulating film.

In yet another example embodiment, a method of manufacturing a semiconductor device having an MIM capacitor includes various steps. First, a metal line is formed on a predeposition layer. Next, a first interlayer insulating film is formed on the predeposition layer so as to cover the metal line. Then, a pair of first via patterns is formed contacting the metal line within the first interlayer insulating film. Next, a lower electrode is formed on the first interlayer insulating film. The lower electrode includes of a pair of metal patterns spaced apart from each other and each contacting one of the first via patterns. Then, a dielectric is formed so as to cover the metal patterns of the lower electrode. Next, a second interlayer insulating film is formed on the dielectric. The second interlayer insulating film has a hole for exposing the lower electrode portion and the first interlayer insulating portion adjacent thereto. Then, a metal plug is formed on the dielectric exposed by the hole. The metal plug fills the hole. Finally, an upper electrode made of a metal is formed on the second interlayer insulating film.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Example embodiments of the present invention will be disclosed in the following description of example embodiments given in conjunction with the accompanying drawings, in which:

FIG. 1 is a cross sectional view of a prior art semiconductor device having an MIM capacitor;

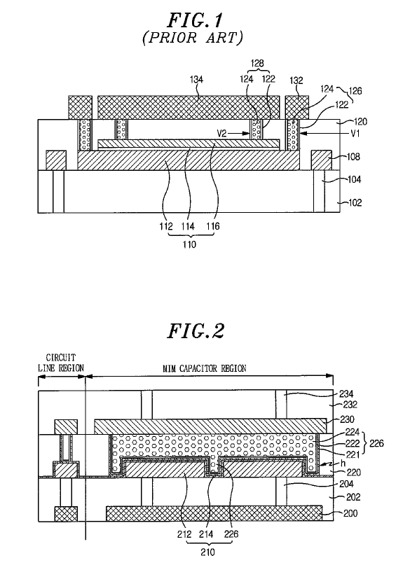

FIG. 2 is a cross sectional view of an example semiconductor device having an example MIM capacitor; and

FIGS. 3A to 3D are process cross sectional views of the example semiconductor device having the example MIM capacitor of FIG. 2.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

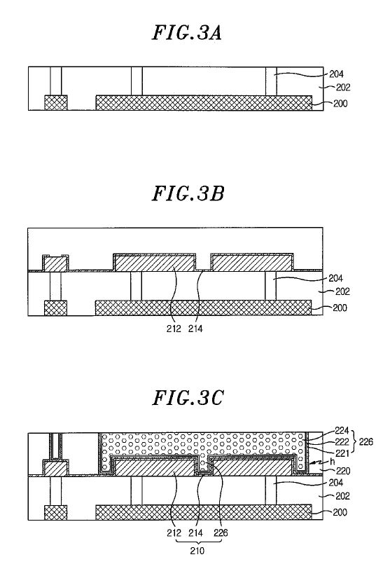

FIG. 2 is a cross sectional view of an example semiconductor device having an example MIM capacitor. As disclosed in FIG. 2, the example MIM capacitor 210 includes a lower electrode 212 including of a pair of metal patterns spaced apart from each other, a dielectric 214 formed so as to cover the surfaces of the metal patterns of the lower electrode 212, and a metal plug 226 formed on the dielectric 214. The pair of metal patterns of the lower electrode 212 may be formed, for example, from Ti/TiN. The dielectric 214 is made of a nitride film and may have a double layer structure. The dielectric 214 is formed on the top surface and side surfaces of the metal patterns of the lower electrode 212. The side surfaces of the metal patterns are used as the capacitor area. The metal plug 226 may be made, for example, from tungsten 222 may further include a barrier film 224. The metal plug 226 has a bridge shape that covers the gaps between the spaced-apart metal patterns and each of the side surfaces of the metal patterns not facing each other.

With continued reference to FIG. 2, a pair of first via patterns 204 is formed under the lower electrode 212 so as to be in contact with the metal patterns of the lower electrode 212. A metal line 200 is formed under the first via patterns 204 so as to be in contact with the first via patterns 204. Further, an upper electrode 230 made of a metal is formed on the second interlayer insulating film 220, and at least one second via pattern 234 is formed to be in contact with upper electrode 230.

With continued reference to FIG. 2, circuit patterns are formed along with the components of each layer of the MIM capacitor 210 in regions adjacent to the MIM capacitor region, and they are vertically connected to each other to thus form a via circuit. The example semiconductor device further includes a first interlayer insulating film 202, a third interlayer insulating film 232, and a hole h.

The example MIM capacitor of FIG. 2 includes the lower electrode 212 including separated metal patterns, the dielectric 214 formed to cover the separated metal patterns, and the metal plug 226, such as a tungsten plug, formed on the dielectric. The example MIM capacitor of FIG. 2, therefore, can obtain an increased capacitance, compared to the prior art in which the top surface alone is used as the electrode surface, by using the side surfaces of the lower electrode as the electrode surface, and accordingly can achieve a desired value of capacitance despite a decrease in the capacitor area caused by high integration. As a result, a merged memory and logic semiconductor device having high performance can be realized.

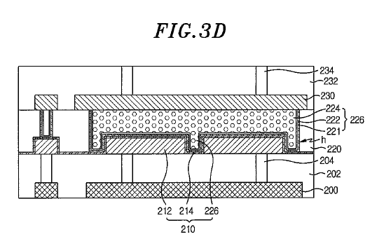

With reference now to FIGS. 3A to 3D, an example method of manufacturing the example semiconductor device having the example MIM capacitor 210 of FIG. 2 will be described.

With reference first to FIG. 3A, a metal line 200 is formed on a predeposition layer (not shown) including a transistor. A first interlayer insulating film 202 is also formed on the predeposition layer so as to cover the metal line 200. The first interlayer insulating film 202 is then etched to thus form via holes for exposing the metal line 200, and then a conductive film is positioned in the via holes to thus form a pair of first via patterns 204 contacting the metal line 200. The first via patterns 204 are spaced apart from each other. Likewise, upon formation of the first via patterns 204, a first via pattern for the via circuit contacting the first metal pattern for the via circuit is formed in a circuit line region.

Referring now to FIG. 3B, a metal film, such as a Ti/TiN film, is deposited on the first interlayer insulating film 202. The metal film is then patterned, thereby forming a lower electrode 212 including a pair of metal patterns spaced apart from each other. Each of the metal patterns of the lower electrode 212 is formed so as to be in contact with one of the first via patterns 204. In the formation of the lower electrode 212, a second metal pattern for the via circuit contacting the first via pattern for the via circuit is formed in the circuit line region. A dielectric 214 is next formed on the lower electrode 212 and the first interlayer insulating film 202. The dielectric 214 may be formed of a nitride film in such a shape as to cover the metal patterns of the lower electrode 212. The material of the dielectric 214 may be deposited at a thickness targeted to the thickness of the portion to be deposited on the side surfaces of the metal patterns of the lower electrode 212, for example, at a thickness between about 300 Å and about 600 Å.

With reference now to FIG. 3C, a second interlayer insulating film 220 is deposited on the dielectric 214, and then the surface of the second interlayer insulating film 220 is planarized by a CMP process. Thereafter, the second interlayer insulating film 220 is etched to form a hole h that exposes the lower electrode 212 and the dielectric 214 formed on the first interlayer insulating film 202 portion adjacent thereto. In the formation of the hole h, the side surfaces of the metal patterns of the lower electrode 212 are covered with the dielectric 214, thus preventing the occurrence of etching damage in the lower electrode 212. Upon formation of the hole h, a hole for the via circuit is formed to expose a second metal pattern for the via circuit formed in the circuit line region.

To compensate for the dielectric lost upon formation of the hole h, a dielectric film 221 is additionally formed on the surface of the hole h including the dielectric 214 portion exposed by the hole h and on the second interlayer insulating film 220. Thereafter, a barrier film 222 is formed on the additionally deposited dielectric film 221, and then tungsten 224 is deposited on the barrier film 222 so as to fill the hole h. Next, CMP is performed on the tungsten 224, the barrier film 222, and the additionally deposited dielectric film 221 so as to expose the second interlayer insulating film 220 to form a metal plug 226, such as a tungsten plug, within the hole h, thereby configuring the MIM capacitor 210.

In one example embodiment, the CMP process for forming the tungsten plug 226 is carried out by setting the dielectrics 221 and 214 made of a nitride film as an End Point Detect (EPD). In this example embodiment, the CMP processing of tungsten prevents the phenomenon of tungsten remaining on the second interlayer insulating film 220 and reduces the possibility of yield reduction. Meanwhile, upon formation of the tungsten plug 226, another tungsten plug having a barrier film is formed within the hole for the via circuit formed in the circuit line region.

With reference now to FIG. 3D, a metal film, such as TiN, is deposited on the second interlayer insulating film 220. The metal film is then patterned, thereby forming an upper electrode 230 contacting the tungsten plug 226. Upon formation of the upper electrode 230, a third metal pattern for the via circuit contacting the other tungsten plug in the circuit line region is formed.

A third interlayer insulating film 232 is next formed on the second interlayer insulating film 220 so as to cover the upper electrode 230. Thereafter, the third interlayer insulating film 232 is etched to form at least one via hole for exposing the upper electrode 230, and a conductive film is positioned in the via holes to thus form second via patterns 234 contacting the upper electrode 230. Upon formation of the second via patterns 234, a second via pattern for the via circuit contacting the third metal pattern for the via circuit is formed in a circuit line region.

Following this, a series of known processes are sequentially performed, thus completing the manufacturing of the example semiconductor device having the example MIM capacitor of FIG. 2.

While example embodiments of the present invention has been illustrated and explained herein, it is to be understood that various modifications can be made to such example embodiments. The scope of the invention is therefore defined in the following claims and their equivalents.

What is claimed is:

1. A semiconductor device having a Metal Insulator Metal (MIM) capacitor, comprising:
a lower electrode comprising a pair of metal patterns spaced apart from each other;
a dielectric formed so as to cover the surfaces of the spaced-apart metal patterns of the lower electrode;
a metal plug formed on the dielectric; and
an upper electrode made of a metal and formed on the metal plug.

2. The semiconductor device of claim 1, further comprising a pair of first via patterns formed under the lower electrode so as to be in contact with the metal patterns of the lower electrode.

3. The semiconductor device of claim 2, further comprising a metal line formed under the first via patterns so as to be in contact with the first via patterns.

4. The semiconductor device of claim 1, further comprising at least one second via pattern formed on the upper electrode so as to be in contact with the upper electrode.

5. The semiconductor device of claim 1, wherein the dielectric is formed so as to cover the bottom and side surfaces of the plug, including the surfaces of the metal patterns of the lower electrode.

6. The semiconductor device of claim 1, wherein the dielectric is made of a nitride film.

7. The semiconductor device of claim 1, wherein the metal plug is made of tungsten and includes a barrier film.

8. A semiconductor device having an MIM capacitor, comprising:
a metal line;
a first interlayer insulating film formed so as to cover the metal line;
a pair of first via patterns spaced apart from each other in the first interlayer insulating film so as to be in contact with the metal line;
a lower electrode including of a pair of metal patterns spaced apart from each other and formed on the first interlayer insulating film so as to be in contact with the first via patterns, respectively;
a second interlayer insulating film formed on the first interlayer insulating film, and having a hole for exposing the lower electrode and the first interlayer insulating film adjacent thereto;
a dielectric formed on the surface of the hole including the surfaces of the metal patterns of the lower electrode;
a metal plug formed on the dielectric so as to fill the hole; and
an upper electrode made of a metal formed on the second interlayer insulating film.

9. The semiconductor device of claim 8, further comprising at least one second via pattern formed on the upper electrode so as to be in contact with the upper electrode.

10. The semiconductor device of claim 8, wherein the dielectric is made of a nitride film.

11. The semiconductor device of claim 8, wherein the metal plug is made of tungsten and includes a barrier film.

12. A method of manufacturing a semiconductor device having an MIM capacitor, comprising the steps of:
forming a metal line on a predeposition layer;
forming a first interlayer insulating film on the predeposition layer so as to cover the metal line;
forming a pair of first via patterns contacting the metal line within the first interlayer insulating film;
forming, on the first interlayer insulating film, a lower electrode including a pair of metal patterns being spaced apart from each other and each contacting one of the first via patterns;
forming a dielectric so as to cover the metal patterns of the lower electrode;
forming, on the dielectric, a second interlayer insulating film having a hole for exposing the lower electrode portion and the first interlayer insulating portion adjacent thereto;
forming, on the dielectric exposed by the hole, a metal plug so as to fill the hole; and
forming an upper electrode made of a metal on the second interlayer insulating film.

13. The method of claim 12, further comprises the step of forming at least one second via pattern contacting the upper electrode.

14. The method of claim 12, wherein the dielectric is formed of a nitride film.

15. The method of claim 12, wherein the nitride film is formed at a thickness targeted to the thickness of the portion formed on the side surfaces of the metal patterns of the lower electrode.

16. The method of claim 15, wherein the nitride film is formed at a thickness between about 300 Å and about 600 Å.

17. The method of claim 12, wherein the step of forming a metal plug comprises the steps of:
additionally depositing a dielectric film on the surface of the hole, including on the dielectric portion exposed by the hole and on the second interlayer insulating film, so as to compensate for the loss of the dielectric;
forming a barrier film on the additionally deposited dielectric film;
depositing tungsten on the barrier film so as to fill the hole; and
performing Chemical Mechanical Polishing (CMP) on the tungsten, the barrier film, and the additionally deposited dielectric film so as to expose the second interlayer insulating film.

18. The method of claim 17, wherein the step of performing CMP on the tungsten, the barrier film, and the additionally deposited dielectric film is carried out by setting the dielectrics made of a nitride film as an End Point Detect (EPD).
